(19) United States
(12) Patent Application Publication
(10) Pub. No.: US 2025/0183013 A1
(43) Pub. Date: Jun. 5, 2025

(54) ELECTROSTATIC CHUCK AND PLASMA PROCESSING APPARATUS INCLUDING THE SAME

(71) Applicant: SEMES CO., LTD., Cheonan-si (KR)

(72) Inventors: Jong Joon JEON, Cheonan-si (KR); Hyung Joon KIM, Cheonan-si (KR); Jong Gun LEE, Cheonan-si (KR); Jun Seok PARK, Cheonan-si (KR)

(73) Assignee: SEMES CO., LTD., Cheonan-si (KR)

(21) Appl. No.: 18/887,575

(22) Filed: Sep. 17, 2024

(30) Foreign Application Priority Data
Dec. 1, 2023 (KR) 10-2023-0172632

(51) Int. Cl. H01J 37/32

(52) U.S. Cl. CPC H01J 37/32724; H01J 37/32449; H01J 37/32697; H01J 2237/334

(57) ABSTRACT

Disclosed are an electrostatic chuck capable of precisely controlling the temperature of a peripheral area of a substrate and a plasma processing apparatus including the same. The electrostatic chuck configured to support a substrate in a plasma processing apparatus includes a plate configured to support the substrate using electrostatic force and having a disc shape, a first partition wall formed in an annular shape on a peripheral portion of the plate, a second partition wall formed in an annular shape at a position farther inward than the first partition wall on the peripheral portion of the plate, and a connection partition wall configured to interconnect the first partition wall and the second partition wall to partition the peripheral portion of the plate into a plurality of peripheral areas.

### CROSS-REFERENCE TO THE RELATED APPLICATION

The present application claims priority to and the benefit of Korean Patent Application No. 10-2023-0172632, filed on Dec. 1, 2023, in the Korean Intellectual Property Office, the entire disclosure of which is incorporated herein by reference.

### BACKGROUND

### Technical Field

The present disclosure relates to an electrostatic chuck and a plasma processing apparatus including the same.

### Description of the Related Art

A semiconductor manufacturing process is a process for manufacturing a semiconductor device on a substrate (e.g., a wafer), and includes, for example, exposure, deposition, etching, ion implantation, and cleaning. In order to perform each manufacturing process, semiconductor manufacturing equipment that performs each process is provided in a clean room of a semiconductor manufacturing plant, and each process is performed on a substrate loaded in the semiconductor manufacturing equipment.

Processes using plasma, for example, etching and deposition, are widely used in the semiconductor manufacturing process. A plasma processing process is performed in such a manner that a substrate is seated at a lower portion in a plasma processing space, fluid for plasma processing is supplied, and voltage is applied by electrodes located at an upper portion and a lower portion in the plasma processing space.

In the plasma processing process, distribution of plasma and the reaction rate (e.g., etch rate) of a substrate are influenced by temperature. Therefore, it is important to maintain a uniform temperature over the entire area of the substrate in the plasma processing process. However, temperature control of a peripheral area of the substrate is more difficult than that of a central area of the substrate. Therefore, there is need for precise control of the temperature of the peripheral area of the substrate.

### SUMMARY

Therefore, the present disclosure has been made in view of the above problems, and it is an object of the present disclosure to provide an electrostatic chuck capable of precisely controlling the temperature of a peripheral area of a substrate and a plasma processing apparatus including the same.

The objects to be accomplished by the disclosure are not limited to the above-mentioned object, and other objects not mentioned herein will be clearly understood by those skilled in the art from the following description.

According to an embodiment of the present disclosure, an electrostatic chuck configured to support a substrate in a plasma processing apparatus includes a plate configured to support the substrate using electrostatic force, the plate having a disc shape, a first partition wall formed in an annular shape on a peripheral portion of the plate, a second partition wall formed in an annular shape at a position farther inward than the first partition wall on the peripheral portion of the plate, and a connection partition wall configured to interconnect the first partition wall and the second partition wall to partition the peripheral portion of the plate into a plurality of peripheral areas.

In the embodiment of the present disclosure, the connection partition wall may include two connection partition walls disposed at positions opposite each other with respect to the center of the plate to partition the peripheral portion of the plate into two peripheral areas.

In the embodiment of the present disclosure, the connection partition wall may include four connection partition walls disposed at angular intervals of 90 degrees about the center of the plate to partition the peripheral portion of the plate into four peripheral areas.

In the embodiment of the present disclosure, a plurality of supply flow paths may be formed in the plate so as to allow inert gas to flow toward the substrate therethrough.

In the embodiment of the present disclosure, the plurality of supply flow paths may include a plurality of periphery-side supply flow paths formed in the plate so as to respectively correspond to the plurality of peripheral areas and a center-side supply flow path formed in the plate at a position farther inward than the plurality of peripheral areas.

In the embodiment of the present disclosure, a pattern may be formed at a position farther inward than the second partition wall on the plate.

In the embodiment of the present disclosure, the pattern may be formed to have a height less than the height of the first partition wall and the height of the second partition wall.

In the embodiment of the present disclosure, the first partition wall may be formed to have a greater width than the second partition wall.

According to another embodiment of the present disclosure, an electrostatic chuck configured to support a substrate in a plasma processing apparatus includes a plate configured to support the substrate using electrostatic force, the plate having a disc shape, a first partition wall formed in an annular shape on a peripheral portion of the plate, a second partition wall formed in an annular shape at a position farther inward than the first partition wall on the peripheral portion of the plate, a connection partition wall configured to interconnect the first partition wall and the second partition wall to partition the peripheral portion of the plate into a plurality of peripheral areas, and a plurality of periphery-side supply flow paths formed in the plate so as to respectively correspond to the plurality of peripheral areas.

In the embodiment of the present disclosure, the flow rate of inert gas supplied to each of the plurality of periphery-side supply flow paths may be individually controlled.

In the embodiment of the present disclosure, the flow rates of inert gas supplied to the plurality of periphery-side supply flow paths may be controlled to differ from each other.

In the embodiment of the present disclosure, a center-side supply flow path may be formed in the plate so as to correspond to a central area of the plate formed at a position farther inward than the plurality of peripheral areas.

In the embodiment of the present disclosure, the flow rate of inert gas supplied to each of the plurality of periphery-side supply flow paths may be controlled to be greater than the flow rate of inert gas supplied to the center-side supply flow path.

According to still another embodiment of the present disclosure, a plasma processing apparatus includes an electrostatic chuck configured to support a substrate using electrostatic force and an inert gas supply device configured to supply inert gas to an upper surface of the electrostatic chuck. The electrostatic chuck includes a ceramic puck configured to allow the substrate to be seated thereon, the ceramic puck accommodating a heater and an electrode therein, a base plate configured to support the ceramic puck, the base plate including a refrigerant flow path formed therein, a bonding layer configured to bond the ceramic puck to the base plate, a ring-shaped sealing member configured to surround an outer side of the bonding layer, a first partition wall formed in an annular shape on a peripheral portion of the ceramic puck, a second partition wall formed in an annular shape at a position farther inward than the first partition wall on the peripheral portion of the ceramic puck, a connection partition wall configured to interconnect the first partition wall and the second partition wall to partition the peripheral portion of the ceramic puck into a plurality of peripheral areas, a plurality of periphery-side supply flow paths formed so as to respectively correspond to the plurality of peripheral areas, and a center-side supply flow path formed at a position farther inward than the plurality of peripheral areas. The inert gas supply device includes an inert gas source configured to store inert gas to be supplied to the plurality of periphery-side supply flow paths and the center-side supply flow path and a flow rate controller configured to individually control the flow rate of inert gas supplied to each of the plurality of periphery-side supply flow paths and the center-side supply flow path.

In the embodiment of the present disclosure, the heater may be provided in plural, and each of the plurality of heaters may be configured such that temperature at which to heat a corresponding one of the plurality of peripheral areas is individually controlled.

### BRIEF DESCRIPTION OF THE DRAWINGS

The accompanying drawings, which are incorporated in this specification, illustrate exemplary embodiments and serve to further illustrate the technical ideas of the disclosure in conjunction with the detailed description of exemplary embodiments that follows, and the disclosure is not to be construed as limited to what is shown in such drawings. In the drawings:

FIG. 1 is a view showing a plasma processing apparatus according to the present disclosure;

FIGS. 2A and 2B are views showing an upper surface of a plate on which partition walls are formed in the plasma processing apparatus according to the present disclosure;

FIG. 3 is a cross-sectional view of the plate having periphery-side partition walls and a central pattern formed thereon; and

FIG. 4 is an enlarged view of a first partition wall and a second partition wall.

### DETAILED DESCRIPTION OF EXEMPLARY EMBODIMENTS

Hereinafter, embodiments of the present disclosure will be described in detail with reference to the accompanying drawings so that those skilled in the art can easily carry out the embodiments. The present disclosure may, however, be embodied in many different forms, and should not be construed as being limited to the embodiments set forth herein.

Parts irrelevant to description of the present disclosure will be omitted to clearly describe the present disclosure, and the same or similar constituent elements will be denoted by the same reference numerals throughout the specification.

In addition, constituent elements having the same configurations in several embodiments will be assigned with the same reference numerals and described only in the representative embodiment, and only constituent elements different from those of the representative embodiment will be described in the other embodiments.

Throughout the specification, when a constituent element is said to be “connected”, “coupled”, or “joined” to another constituent element, the constituent element and the other constituent element may be “directly connected”, “directly coupled”, or “directly joined” to each other, or may be “indirectly connected”, “indirectly coupled”, or “indirectly joined” to each other with one or more intervening elements interposed therebetween. In addition, throughout the specification, when a constituent element is referred to as “comprising”, “including”, or “having” another constituent element, the constituent element should not be understood as excluding other elements, so long as there is no special conflicting description, and the constituent element may include at least one other element.

Unless otherwise defined, all terms used herein, which include technical or scientific terms, have the same meanings as those generally appreciated by those skilled in the art. The terms, such as ones defined in common dictionaries, should be interpreted as having the same meanings as terms in the context of pertinent technology, and should not be interpreted as having ideal or excessively formal meanings unless clearly defined in the specification.

The present disclosure relates to an electrostatic chuck 10 and a plasma processing apparatus 1 including the electrostatic chuck 10, and more particularly, to an electrostatic chuck 10 for supporting a substrate W in the plasma processing apparatus 1 and a structure thereof capable of precisely controlling the temperature of a peripheral area of the substrate W.

The plasma processing apparatus 1 is equipment for performing plasma processing (e.g., dry etching) on the substrate W. When the substrate W is loaded in the plasma processing apparatus 1, high-frequency power is applied to an upper electrode and a lower electrode to generate an electromagnetic field, and a process gas supplied to the substrate W transitions to a plasma state due to the electromagnetic field, and reacts with a specific material of the substrate W. The substrate W having undergone plasma processing for a certain period of time is discharged to the outside of the plasma processing apparatus 1, and subsequent processing processes are performed.

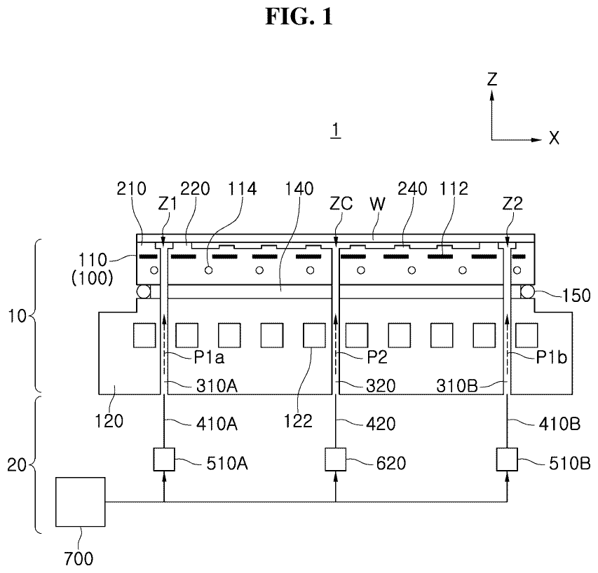

FIG. 1 is a view showing a plasma processing apparatus 1 according to the present disclosure. Referring to FIG. 1, the plasma processing apparatus 1 includes an electrostatic chuck 10 configured to support a substrate using electrostatic force and an inert gas supply device 20 configured to supply inert gas to the upper surface of the electrostatic chuck 10.

The electrostatic chuck 10 includes a ceramic puck 110, on which a substrate W is seated and in which a heater 114 and an electrode 112 are mounted, a base plate 120 configured to support the ceramic puck 110 and having a refrigerant flow path 122 formed therein, a bonding layer 140 configured to bond the ceramic puck 110 to the base plate 120, and a ring-shaped sealing member 150 configured to surround an outer side of the bonding layer 140.

The temperature of the electrostatic chuck 10 is adjusted by the heater 114 and the refrigerant flow path 122, and the inert gas supply device 20 supplies inert gas (e.g., He) so that the temperature of the electrostatic chuck 10 is transferred to the substrate W.

The ceramic puck 110 is a structure configured to support the substrate W from below, and is provided therein with the electrode 112 and the heater 114. The ceramic puck 110 may be made of a ceramic material (e.g., quartz). The ceramic puck 110 is a plate 100 that supports the substrate using electrostatic force and has a disc shape. The upper surface of the ceramic puck 110 is a surface that contacts the substrate W. A pattern 240 forming a flow path along which inert gas flows is formed on the central portion of the upper surface of the ceramic puck 110. A first partition wall 210, a second partition wall 220, and a connection partition wall 230 are formed on the peripheral portion of the upper surface of the ceramic puck 110.

The base plate 120 is formed in a disc shape made of metal (e.g., Al). The base plate 120 may include a lower region having a predetermined diameter and an upper region having a smaller diameter than the lower region. The refrigerant flow path 122 may be formed in the lower region of the base plate 120. The upper region of the base plate 120 may be coupled to the ceramic puck 110. That is, the base plate 120 may have a shape in which the lower region protrudes. Although not shown in the drawings, an edge ring (not shown) for control of plasma with respect to the peripheral portion of the substrate W may be provided on the protruding portion of the base plate 120.

A coating layer made of alumina (Al₂O₃) may be formed on an outer surface of the base plate 120. The coating layer prevents the base plate 120 made of metal (e.g., Al) from being exposed to the external environment, particularly, plasma.

The bonding layer 140 is formed between the ceramic puck 110 and the base plate 120 to bond the ceramic puck 110 to the base plate 120. The base plate 120 and the ceramic puck 110 may be bonded to each other by means of the bonding layer 140 made of an adhesive material. The ring-shaped sealing member 150 may be provided between the ceramic puck 110 and the base plate 120 so as to surround an outer side of the bonding layer 140. The sealing member 150 seals the bonding layer 140, thereby preventing the bonding layer 140 from being exposed to the external environment, particularly, plasma.

In addition, the electrostatic chuck 10 includes a first partition wall 210 formed in an annular shape on the peripheral portion of the ceramic puck 110, a second partition wall 220 formed in an annular shape at a position farther inward than the first partition wall 210 on the peripheral portion of the ceramic puck 110, and a connection partition wall 230 interconnecting the first partition wall 210 and the second partition wall 220 and partitioning the peripheral portion of the ceramic puck 110 into a plurality of peripheral areas. The first partition wall 210, the second partition wall 220, and the connection partition wall 230 partition the peripheral portion of the ceramic puck 110 into a plurality of peripheral areas, and enable more precise temperature control for each individual peripheral area. Hereinafter, for convenience of explanation, the ceramic puck 110 will be referred to as a plate 100.

In addition, the electrostatic chuck 10 includes a plurality of periphery-side supply flow paths 310A and 310B formed so as to respectively correspond to peripheral areas Z1 and Z2 and a center-side supply flow path 320 formed at a position farther inward than the peripheral areas Z1 and Z2.

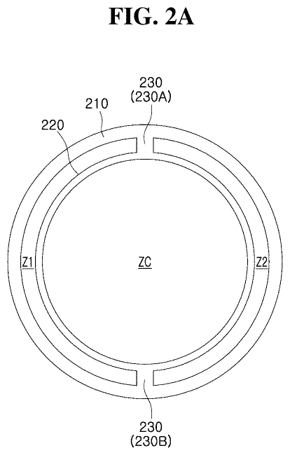

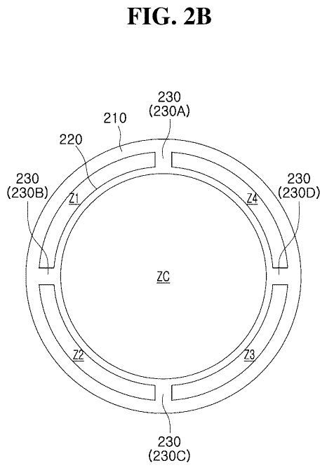

FIGS. 2A and 2B are views showing the upper surface of the plate 100 on which the partition walls are formed in the plasma processing apparatus 1 according to the present disclosure. FIG. 2A is a view showing a case in which the peripheral portion of the plate 100 is partitioned into two peripheral areas, and FIG. 2B is a view showing a case in which the peripheral portion of the plate 100 is partitioned into four peripheral areas.

Referring to FIGS. 2A and 2B, the first partition wall 210 is formed in an annular shape on the outermost peripheral portion of the plate 100. The second partition wall 220 is formed in an annular shape at a position spaced a predetermined distance from an inner side of the first partition wall 210. The peripheral areas of the plate 100 are isolated from a central area ZC, which is formed at the central portion of the plate 100, by the first partition wall 210 and the second partition wall 220. A portion of the first partition wall 210 and a portion of the second partition wall 220 are connected to each other via the connection partition wall 230. As shown in FIG. 2A, the connection partition wall 230 is formed at each of the 12 o'clock position and the 6 o'clock position, and accordingly, the peripheral portion of the plate 100 is partitioned into two peripheral areas. That is, the connection partition wall 230 may include two connection partition walls 230A and 230B disposed at positions opposite each other with respect to the center of the plate 100 to partition the peripheral portion of the plate 100 into two peripheral areas.

As shown in FIG. 2B, the connection partition wall 230 is formed at each of the 12 o'clock position, the 3 o'clock position, the 6 o'clock position, and the 9 o'clock position, and accordingly, the peripheral portion of the plate 100 is partitioned into four peripheral areas. That is, the connection partition wall 230 may include four connection partition walls 230A, 230B, 230C, and 230D disposed at angular intervals of 90 degrees about the center of the plate 100 to partition the peripheral portion of the plate 100 into four peripheral areas Z1, Z2, Z3, and Z4.

Although FIGS. 2A and 2B illustrate the cases in which the peripheral portion of the plate 100 is partitioned into two peripheral areas and the case in which the peripheral portion of the plate 100 is partitioned into four peripheral areas, the number and shape of peripheral areas are not limited to the illustrated cases, and may be varied. Hereinafter, for convenience of explanation, the present disclosure will be described based on the case in which two peripheral areas are formed.

In the embodiment of the present disclosure, a plurality of supply flow paths, through which inert gas flows to be supplied to the substrate W, is formed in the plate 100. The supply flow paths include a plurality of periphery-side supply flow paths 310A and 310B formed so as to respectively correspond to the peripheral areas Z1 and Z2 of the plate 100 and a center-side supply flow path 320 formed at a position farther inward than the peripheral areas Z1 and Z2 in the plate 100. Referring to FIG. 1, the peripheral portion of the plate 100 is partitioned into a first peripheral area Z1 and a second peripheral area Z2, the first supply flow path 310A is formed corresponding to the first peripheral area Z1, and the second supply flow path 310B is formed corresponding to the second peripheral area Z2. The center-side supply flow path 320 is formed corresponding to the central area ZC of the plate 100.

The inert gas supply device 20 supplies inert gas to the supply flow paths formed in the electrostatic chuck 10. The inert gas supply device 20 includes inert gas sources 510A, 510B, and 620 configured to store inert gas to be supplied to the periphery-side supply flow paths 310A and 310B and the center-side supply flow path 320 and a flow rate controller 700 configured to individually control the flow rate of inert gas supplied to each of the periphery-side supply flow paths 310A and 310B and the center-side supply flow path 320. The inert gas sources 510A, 510B, and 620 store inert gas. The inert gas sources 510A, 510B, and 620 may temporarily store inert gas supplied from the outside, and may supply the inert gas at a set flow rate (pressure). The inert gas sources 510A, 510B, and 620 may be implemented as a single integral tank, or may be provided separately from each other. Flow rate control valves configured to allow or interrupt the supply of inert gas and to control the flow rate of the inert gas may be provided on flow paths between the inert gas sources 510A, 510B, and 620 and the supply flow paths (i.e., the periphery-side supply flow paths 310A and 310B and the center-side supply flow path 320). The flow rate controller 700 may control the flow rate of the inert gas supplied from the inert gas sources 510A, 510B, and 620 to the periphery-side supply flow paths 310A and 310B and the center-side supply flow path 320 through the flow rate control valves.

The flow rate controller 700 may perform control such that the flow rates of the inert gas supplied to the respective periphery-side supply flow paths 310A and 310B differ from each other. For example, when rapid temperature control is required for the first peripheral area Z1, the flow rate controller 700 may perform control such that the flow rate P1a of the inert gas supplied to the first peripheral area Z1 is greater than the flow rate P1b of the inert gas supplied to the second peripheral area Z2.

In addition, the flow rate controller 700 may control the flow rate P2 of the inert gas supplied to the center-side supply flow path 320 formed at a position farther inward than the peripheral areas Z1 and Z2 in the plate 100. The flow rate controller 700 may perform control such that the flow rates P1a and P1b of the inert gas supplied to the periphery-side supply flow paths 310A and 310B are greater than the flow rate P2 of the inert gas supplied to the center-side supply flow path 320. It is possible to more precisely control the temperature of the peripheral portion of the substrate W by increasing the flow rates P1a and P1b of the inert gas supplied to the periphery-side supply flow paths 310A and 310B to be greater than the flow rate P2 of the inert gas supplied to the center-side supply flow path 320.

In the embodiment of the present disclosure, a pattern 240 is formed at a position farther inward than the second partition wall 220 on the plate 100. The pattern 240 formed in the central area ZC of the upper surface of the plate 100 forms a flow path along which inert gas flows. The inert gas supplied to the central area ZC flows along the flow path formed by the pattern 240. The pattern 240 serves to guide the inert gas so that the inert gas is evenly distributed over the entire area of the substrate W. The pattern 240 protrudes from the upper surface of the plate 100.

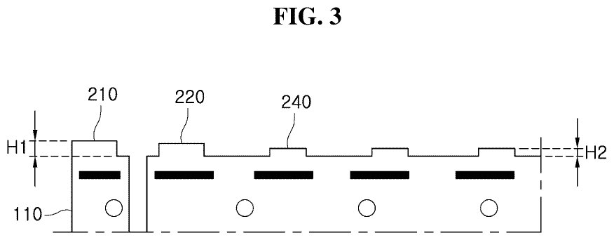

FIG. 3 is a cross-sectional view of the plate 100 having the periphery-side partition walls 210 and 220 and the central pattern 240 formed thereon. Referring to FIG. 3, the first partition wall 210 and the second partition wall 220 are formed on the peripheral portion of the plate 100, and the pattern 240 is formed on the central portion of the plate 100. The first partition wall 210 and the second partition wall 220 have the same height. The height H2 of the pattern 240 is formed to be less than the heights of the first partition wall 210 and the second partition wall 220. Accordingly, the substrate W may be stably supported by the first partition wall 210 and the second partition wall 220, and the temperature of the peripheral portion of the substrate W may be more precisely controlled by inert gas in the peripheral areas Z1 and Z2. In another embodiment, the height of the first partition wall 210 may be formed to be greater than the height of the second partition wall 220. In this case, it is possible to more stably support a substrate having a peripheral portion warped in the upward direction.

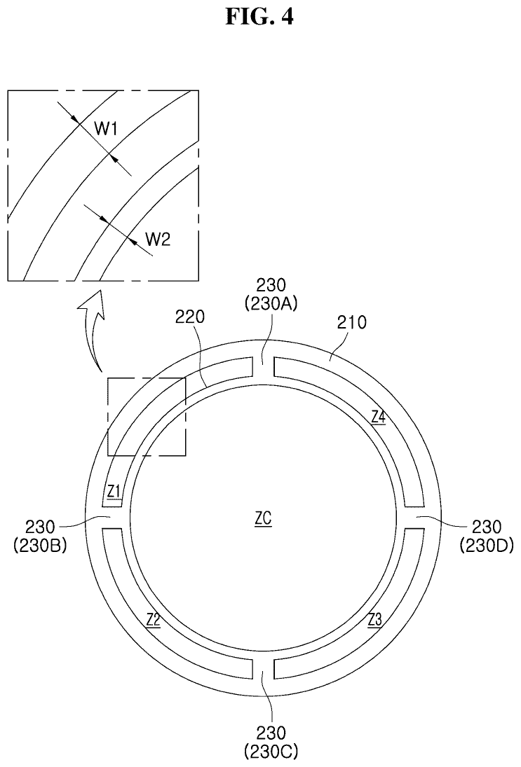

FIG. 4 is an enlarged view of the first partition wall 210 and the second partition wall 220. Referring to FIG. 4, the width W1 of the first partition wall 210 is formed to be greater than the width W2 of the second partition wall 220. As such, since the first partition wall 210 has a greater width than the second partition wall 220, the peripheral portion of the substrate W may be more stably supported, and the temperature of the peripheral portion of the substrate W may be more precisely controlled by inert gas in the peripheral areas Z1, Z2, Z3, and Z4.

In the present disclosure, in order to individually control the temperature of each of the peripheral areas Z1 and Z2 partitioned by the first partition wall 210, the second partition wall 220, and the connection partition wall 240, the heater 114 may be provided at a position corresponding to each of the peripheral areas Z1 and Z2. In an example, the heater 114 may include a first heater configured to heat the first peripheral area Z1, a second heater configured to heat the second peripheral area Z2, and a third heater configured to heat the central area ZC. That is, the heater 114 may be provided in plural, and each of the plurality of heaters 114 may be configured such that output thereof is controlled for a corresponding one of the peripheral areas so that temperature at which to heat a corresponding one of the peripheral areas is individually controlled.

As is apparent from the above description, according to the present disclosure, a peripheral portion of a ceramic puck of an electrostatic chuck may be partitioned into a plurality of peripheral areas by partition walls, and inert gas for temperature control may be individually supplied to each of the partitioned peripheral areas, whereby the temperature of the peripheral portion of a substrate may be precisely controlled.

The effects achievable through the disclosure are not limited to the above-mentioned effects, and other effects not mentioned herein will be clearly understood by those skilled in the art from this specification and the accompanying drawings.

Although the preferred embodiments of the present disclosure have been disclosed for illustrative purposes, those skilled in the art will appreciate that various modifications, additions and substitutions are possible, without departing from the scope and spirit of the disclosure.

The scope of the present disclosure should be defined only by the appended claims, and all technical ideas within the scope of equivalents to the claims should be construed as falling within the scope of the disclosure.

What is claimed is:

1. An electrostatic chuck configured to support a substrate in a plasma processing apparatus, the electrostatic chuck comprising:
a plate configured to support the substrate using electrostatic force, the plate having a disc shape;
a first partition wall formed in an annular shape on a peripheral portion of the plate;
a second partition wall formed in an annular shape at a position farther inward than the first partition wall on the peripheral portion of the plate; and
a connection partition wall configured to interconnect the first partition wall and the second partition wall to partition the peripheral portion of the plate into a plurality of peripheral areas.

2. The electrostatic chuck as claimed in claim 1, wherein the connection partition wall comprises two connection partition walls disposed at positions opposite each other with respect to a center of the plate to partition the peripheral portion of the plate into two peripheral areas.

3. The electrostatic chuck as claimed in claim 1, wherein the connection partition wall comprises four connection partition walls disposed at angular intervals of 90 degrees about a center of the plate to partition the peripheral portion of the plate into four peripheral areas.

4. The electrostatic chuck as claimed in claim 1, further comprising a plurality of supply flow paths formed in the plate so as to allow inert gas to flow toward the substrate therethrough.

5. The electrostatic chuck as claimed in claim 4, wherein the plurality of supply flow paths comprises:
a plurality of periphery-side supply flow paths formed in the plate so as to respectively correspond to the plurality of peripheral areas; and
a center-side supply flow path formed in the plate at a position farther inward than the plurality of peripheral areas.

6. The electrostatic chuck as claimed in claim 1, further comprising a pattern formed at a position farther inward than the second partition wall on the plate.

7. The electrostatic chuck as claimed in claim 6, wherein the pattern is formed to have a height less than a height of the first partition wall and a height of the second partition wall.

8. The electrostatic chuck as claimed in claim 1, wherein the first partition wall is formed to have a greater width than the second partition wall.

9. An electrostatic chuck configured to support a substrate in a plasma processing apparatus, the electrostatic chuck comprising:
a plate configured to support the substrate using electrostatic force, the plate having a disc shape;
a first partition wall formed in an annular shape on a peripheral portion of the plate;
a second partition wall formed in an annular shape at a position farther inward than the first partition wall on the peripheral portion of the plate;
a connection partition wall configured to interconnect the first partition wall and the second partition wall to partition the peripheral portion of the plate into a plurality of peripheral areas; and
a plurality of periphery-side supply flow paths formed in the plate so as to respectively correspond to the plurality of peripheral areas.

10. The electrostatic chuck as claimed in claim 9, wherein a flow rate of inert gas supplied to each of the plurality of periphery-side supply flow paths is individually controlled.

11. The electrostatic chuck as claimed in claim 9, wherein flow rates of inert gas supplied to the plurality of periphery-side supply flow paths are controlled to differ from each other.

12. The electrostatic chuck as claimed in claim 9, further comprising a center-side supply flow path formed in the plate so as to correspond to a central area of the plate formed at a position farther inward than the plurality of peripheral areas.

13. The electrostatic chuck as claimed in claim 12, wherein a flow rate of inert gas supplied to each of the plurality of periphery-side supply flow paths is controlled to be greater than a flow rate of inert gas supplied to the center-side supply flow path.

14. A plasma processing apparatus comprising:
an electrostatic chuck configured to support a substrate using electrostatic force; and
an inert gas supply device configured to supply inert gas to an upper surface of the electrostatic chuck,
wherein the electrostatic chuck comprises:
a ceramic puck configured to allow the substrate to be seated thereon, the ceramic puck accommodating a heater and an electrode therein;
a base plate configured to support the ceramic puck, the base plate comprising a refrigerant flow path formed therein;
a bonding layer configured to bond the ceramic puck to the base plate;
a ring-shaped sealing member configured to surround an outer side of the bonding layer;
a first partition wall formed in an annular shape on a peripheral portion of the ceramic puck;
a second partition wall formed in an annular shape at a position farther inward than the first partition wall on the peripheral portion of the ceramic puck;
a connection partition wall configured to interconnect the first partition wall and the second partition wall to partition the peripheral portion of the ceramic puck into a plurality of peripheral areas;
a plurality of periphery-side supply flow paths formed so as to respectively correspond to the plurality of peripheral areas; and
a center-side supply flow path formed at a position farther inward than the plurality of peripheral areas, and
wherein the inert gas supply device comprises:
an inert gas source configured to store inert gas to be supplied to the plurality of periphery-side supply flow paths and the center-side supply flow path; and
a flow rate controller configured to individually control a flow rate of inert gas supplied to each of the plurality of periphery-side supply flow paths and the center-side supply flow path.

15. The plasma processing apparatus as claimed in claim 14, wherein the heater is provided in plural, and each of the plurality of heaters is configured such that output thereof is controlled for a corresponding one of the plurality of peripheral areas so that a temperature at which to heat a corresponding one of the plurality of peripheral areas is individually controlled.

16. The plasma processing apparatus as claimed in claim 14, wherein the connection partition wall comprises four connection partition walls disposed at angular intervals of 90 degrees about a center of the ceramic puck to partition the peripheral portion of the ceramic puck into four peripheral areas.

17. The plasma processing apparatus as claimed in claim 14, further comprising a pattern formed at a position farther inward than the second partition wall on the ceramic puck.

18. The plasma processing apparatus as claimed in claim 17, wherein the pattern is formed to have a height less than a height of the first partition wall and a height of the second partition wall.

19. The plasma processing apparatus as claimed in claim 14, wherein the first partition wall is formed to have a greater width than the second partition wall.

20. The plasma processing apparatus as claimed in claim 14, wherein the flow rate controller performs control such that flow rates of inert gas supplied to the plurality of periphery-side supply flow paths differ from each other.
